(19) United States
(12) Patent Application Publication
(10) Pub. No.: US 2017/0149401 A1
(43) Pub. Date: May 25, 2017

(54) EQUALISER, AUDIO SYSTEM WITH SUCH AN EQUALISER AND METHOD OF EQUALISING A SOUND MIX

(71) Applicant: Bernhard Schwede, München (DE)

(72) Inventor: Bernhard Schwede, München (DE)

(21) Appl. No.: 15/127,349

(22) PCT Filed: Mar. 24, 2015
(86) PCT No.: PCT/EP2015/056254

§ 371 Date: Sep. 19, 2016

(30) Foreign Application Priority Data
Mar. 25, 2014 (DE) 20 2014 101 373.3

(51) Int. Cl. H03G 5/16; H03G 9/02

(52) U.S. Cl. CPC H03G 5/165; H03G 9/025

(57) ABSTRACT

An equaliser for aurally compensated equalisation of a sound mix consisting of sounds of various frequencies (f) generates an equalisation curve (P(f)), which shows a frequency-dependent change in sound levels (P) of sounds, and for frequencies fE(n)=kn·f0 has extremes (P(n)=P(f(n))) and for frequencies fN(n)=k(n−1/2)·f0 has zero points (N(n)=N(f(n))), with (formula (I)), f0 of a frequency of a predefined extreme (P(0)) and 1.52≦k≦1.82.

### CROSS-REFERENCE TO RELATED APPLICATIONS

The present application is a 35 U.S.C. §371 national phase application of PCT/EP2015/056254 with international filing date of Mar. 24, 2015 and claims priority thereto, and further claims priority to application No. DE 20/2014/101,373.3 filed on Mar. 25, 2014. The above-identified applications are incorporated herein by reference in their entirety for all purposes

### STATEMENT REGARDING FEDERALLY SPONSORED RESEARCH OR DEVELOPMENT

Not applicable.

### BACKGROUND

The present invention relates to an equaliser, an audio system with such an equaliser and a method of equalising a sound mix.

In particular, the present invention relates to an equaliser/an audio system/a method of aurally compensated equalisation of a sound mix.

A person perceives acoustic stimuli or sound through his/her hearing or auditory system. The hearing system includes the outer ear, the middle ear with the auditory ossicles and the inner ear with the cochlea and nerves connected thereto, as well as the auditory stimulus processing centres located in the cerebrum and brain stem. Because of this complex anatomy and its to this day unexplainable detailed physiology and manner of functioning, the perception of auditory stimuli is not linear, i.e. equally intensive for all wavelengths. Instead, there is a spectral (frequency-dependent) auditory sensitivity which is also dependent on loudness.

The dependence on loudness in particular results, for example, in a piece of music being played back from a sound storage medium in a room which is small compared to a concert hall sounding unnatural in comparison with the live experience. It is known that this unnaturalness can be eliminated by correcting the volume as a mirror-image to auditory sensitivity, which is shown in so-called “curves of equal volume levels”. However, it has been shown that the current curves used for this only conditionally reconstruct the required naturalness of the sound as in order to determine them individual sinusoidal tones have to be played to the test persons, but the perceived loudness of each individual frequency is influenced by the loudness of other simultaneously perceived frequencies. More particularly the music is too bassy so that room information, transients, transient effects, timbres of musical instruments, reverberations etc. are less audible due to so-called masking effects which makes the recording seem imprecise and spongy. This effect is also intensified by any overemphasis of the middle tones as through this the audible very sensitive balance of fundamental and overtones in musical instruments, which constitutes the particular sound and characteristic of an instrument, is displaced.

### SUMMARY OF THE DISCLOSURE

The present disclosure provides an equaliser which through optimum balancing of all auditory non-linearities produces the greatest possible naturalness of a sound mix, particularly music, at all volumes.

An equaliser according to the present disclosure equalises in an aurally compensated manner a sound mix of sounds of different frequencies (f) according to an equalising curve (P(f)) which shows a frequency-dependent change in sound levels (P) of the sounds and at frequencies f₍ₙ₎^{E}=kⁿ·f₀ has extremes (P(n)≡P(f(_{fn})) and at frequencies f₍ₙ₎^{N}=k^{(n-1/2)}·f₀ zero points (N(n)≡N(f₍ₙ₎), wherein n ε N, f₀ is a frequency of a predetermined extreme (P(0)) and 1.5² ≦k≦1.8².

“Equalisation” in accordance with the present disclosure is a frequency-dependent “change of sound levels (P)” (in decibels (dB)), wherein the entirety of all simultaneously perceived sounds with their associated sound level is designated as “loudness” and is a parameter defined by standards for the proportional depiction of loudness perception by humans. The unit of loudness is the sone, which in turn is based on the definition of the sound level(or simply the “loudness”) in phons.

In particular, a sound intensity of 40 phons is assigned a loudness of 1 sone, wherein a sound intensity of 40 phones is defined by the loudness of a sinusoidal sound with a frequency of 1 kHz and a sound pressure level of 40 dB.

The equalisation curve may be a constant, differentiable function of frequency f. Equalisation according to the disclosure is based on the knowledge that “measuring linearity” does not mean the same as “auditory linearity”, as reference is made here to human hearing which reacts differently to different frequencies at different loudnesses. This fact was investigated by Fletcher and Munson as long ago as 1933 and resulted in the “psychoacoustic curves of equal loudness” which are set out in ISO standard 226:2003—the version of the ISO recommendations 226 corrected in 2003—and DIN 45630 sheet 2 (DIN 1318). Equalising a sound mix in accordance with these curves achieves that sound recordings can be reproduced in such a way that they produce a similar auditory impression at different loudness levels. This form of equalisation adapted to human hearing is called “aural compensation”. An aurally compensated sound recording is perceived as “natural”.

According to the present disclosure, the equaliser is not, as indicated above, used on pure sinusoidal sounds (measuring sounds) but on a “sound mix” which includes sounds of different frequencies and produced by different musical instruments. A sound mix according to DIN 1320 is in particular a sound made up of tones of any frequency and also contains “noises” as non-periodic special forms. In addition, the equaliser according to the disclosure takes into account the changes in a recorded sound mix due to the environment in which it is played back.

As the equaliser according to the disclosure is arranged upstream of a sound transducer of an audio system, so that the equalisation is applied to the sound mix produced by the audio system, it relates to all sounds including the overtones and thus the tone colour, which regains its “naturalness” through the equalisation.

As under certain circumstances people make different statements about the sound mix/tone they perceive as “natural”, i.e. the term “naturalness” is therefore subjective, numerous experiments were conducted by the inventor of the inventions disclosed herein.

More particularly, a digital 31 band graphic equaliser was used which produces no time or phase shifting and allows standardised frequency ranges to be increased or reduced in 0.5 dB steps. The experimentally determined curves could be stored and their effect on the sound mix could be compared with each other and with linear reproductions. Numerous variations of a possible correction curve were subject to systematically designed hearing tests, wherein pieces of music, films, instrumental and vocal recordings and even live events were used. In all studio experiments near field monitors were used, wherein as a parameter the loudness was varied and monitored by means of a sound level meter.

According to the disclosure, the equalisation curves have extremes and zero points which depend on k, wherein 1.5²≦k≦1.8² applies. Preferably k has the value 1.618. It should be noted that the figure 1.618 is an approximation of the irrational golden number which describes the golden ratio: for example if a distance of length s is divided according to the golden ratio into a larger section g and a smaller section k then s/g=g/k=1.1618=the golden ratio. To arrive at the result from the example of length, the unit of length (arbitrarily selected in the example) only has to be replaced with frequency.

The figure 1.618 is also a limit value

$${lim}_{n -> ∞} \frac{{f}_{n + 1}}{{f}_{n}}$$

of the recursively defined Fibonacci series, wherein each element fn of a series of natural number is defined according to the rule fₙ₋₂=fₙ−fₙ₋₁ frp, from the two preceding elements of the series and f₀=0 and f₁=1 is defined as the starting point.

From the definition of the position of the extremes and zero points it is evident that the equalisation curve is an oscillating but not a periodic function of the frequency f.

In certain dislcosed embodiments, the following applies for all n: |P(n)|>|P(n−1)|.

This means that (in terms of amount) the amplitudes of the equalisation curve decrease with increasing frequency. This decrease takes place at all sound levels. It should be noted that the signs of the amount, as in the following, come into play when the sound level zero line is applied to the equalisation curve.

In certain dislcosed embodiments, the difference in amount |P(n)|−|P(n+1)| is constant for all n.

This means, for example, that in a diagram in which the loudness is shown in decibels as a function of the logarithmically entered frequency (equalisation curve) all points (f(n), |P(n)|) lie on a straight line.

In certain dislcosed embodiments, |P(n)|−|P(n+1)| is less than or equal to 2 dB (decibels) for all n.

The value of 2 dB applies for a relatively quiet sound mix with a relatively low sound level or loudness, wherein “relatively quiet” means around 70 dB and “relatively loud” would be around 80 dB.

In certain dislcosed embodiments, |P(n)|−|P(n+1)|>|P(n+1)−P(n+2)| applies for all n.

The difference in the absolute amounts of loudness thus becomes smaller with increasing frequency so that in the aforementioned diagram the curve, on which the points (f(n), |P(n)|) lies does not produce a straight line.

In certain dislcosed embodiments, a ratio

$$\vert \frac{P ( n )}{P ( n + 1 )} \vert$$

for a given n increases with increasing loudness of the sound mix.

The ratio

$$\vert \frac{P ( n )}{P ( n + 1 )} \vert$$

is normally frequency-dependent so that the ratio has to relate to a predetermined n.

In certain dislcosed embodiments, f₀=1.2 kHz applies.

Alternatively, standard pitch can be taken as starting point, i.e. f₀=440 Hz.

In certain dislcosed embodiments, for each frequency interval f₍ₙ₎^{N}≦f≦f₍ₙ₊₁₎^{N} is either

$$\frac{{d}^{2}}{d {f}^{2}} P ( f ) < 0 or \frac{{d}^{2}}{d {f}^{2}} P ( f ) > 0.$$

Through this the “sinusoidality” (of “wavelikeness”) of the equalisation curve should be expressed. This means that the equalisation curve resembles a sinus wave but is not periodic. The first expression

$$\frac{{d}^{2}}{d {f}^{2}} P ( f ) < 0$$

relates to lower “half waves” or wave troughs (with minima),

whereas the second expression

$$\frac{{d}^{2}}{d {f}^{2}} P ( f ) > 0$$

relates to upper half waves or wave peaks (with maxima). In certain dislcosed embodiments, it also follows that the equalisation curve as well as the sine wave is constant and differentiable.

It should be noted that the wavelikeness of the equalisation curve reflects the spectral (i.e. frequency-dependent) sensitivity of human hearing in both senses. On the one hand in the sense of “reproduces” and on the other hand in the sense of “mirrors”, i.e. the equalisation curve is a reflection of the sensitivity curve of human hearing at its zero line.

In certain dislcosed embodiments, the frequency-dependent change of sound levels is a frequency-dependent decrease and increase of the sound level.

A decrease in sound levels has the advantage over an increase in sound levels that phase shifting can thereby be avoided. In practical application in which the equalisation curve is produced with a finite number of regulators, in the case of a decrease all regulators are displaced from their neutral position in the same direction.

In certain dislcosed embodiments, an audio system with an input, an output and a sound transducer connected to the output comprises an equaliser which in a reproduction chain of the audio system is arranged upstream of the sound transducer.

This means that the equaliser according to the disclosure is applied to the entire signal emitted by the audio system and thus equalises the “distorted” signal issued to the audio system.

In certain dislcosed embodiments, for the aural compensation of a sound mix of sounds of different frequencies (f) the extent of equalisation is determined by an equalisation curve (P(f)) which exhibits a frequency-dependent change of sound levels (P) of the sounds and at frequencies of f₍ₙ₎^{E}=kⁿ·f₀ has extremes (P(n)=P(f₍ₙ₎))and at frequencies of f₍ₙ₎^{N}=k^{(n-1/2)}·f₀ as zero points (N(n)=N(fₙ))) with n ε N, f0 as a frequency of a predetermined extreme (P(0)) and 1.5²≦k≦1.8².

In certain dislcosed embodiments, the equalisation curve (P(f)) has the form of damped oscillation which attenuates with increasing frequency of the sound mix.

In certain dislcosed embodiments, a ratio

$$\vert \frac{P ( n )}{P ( n + 1 )} \vert$$

becomes greater with increasing loudness of the sound mix.

### BRIEF DESCRIPTION OF THE DRAWINGS

Other characteristics and features of the present disclosure are evident from the following description with reference to the figures in which examples of equalisation curves are explained. In these figures:

FIGS. 1A and 1B show an equalisation curve for a right and a left channel according to a first form of embodiment;

FIGS. 2A and 2B compare an equalisation curve according to FIG. 1 (bottom) with an equalisation curve according to a second form of embodiment (top), and

FIGS. 3A and 3B compare an equalisation curve according to FIG. 1 (bottom) with a hearing sensitivity curve (top).

### DETAILED DESCRIPTION OF EXEMPLARY EMBODIMENTS

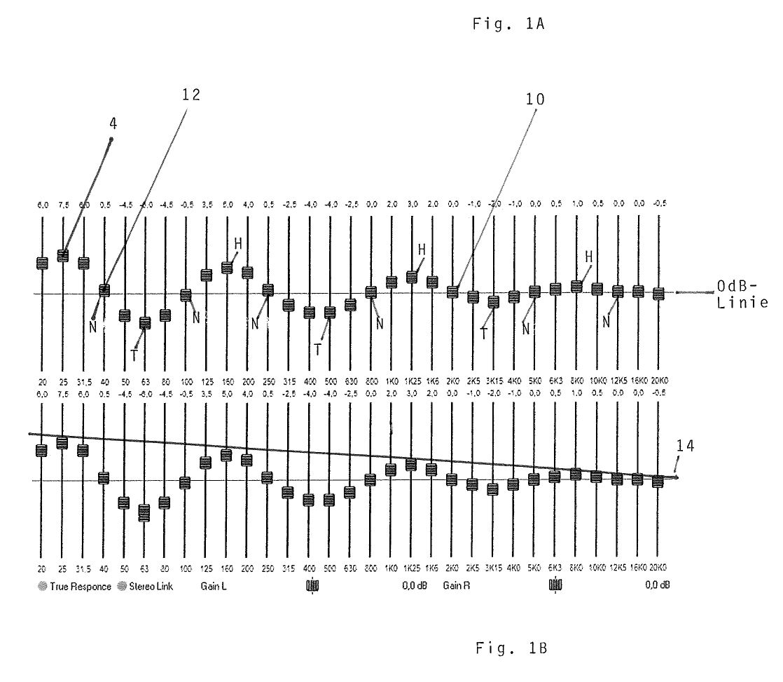

FIGS. 1A and 1B show equalisation curves 10 for a right (top) and a left (bottom) channel according to a first form of embodiment (only FIG. 1A is provided with reference number, FIG. 1B is equivalent).

FIGS. 1A and 1B show the frequency-dependent correction—decrease or increase with regard to a ‘zero line N’—of the sound level (loudness), wherein in each case the frequency is entered along the bottom and logarithmically and the correction in decibels along the top. The corrections are shown by the position of regulators 12. If a regulator is on the zero dB line, the associated frequency remains unchanged. The wavelike structure, which differs from the known equalisation curves, and attenuates towards higher frequencies can be clearly seen.

As shown in FIGS. 1A and 1B, the increase maxima (highest points H of the equalisation curve 10) are at frequencies 25 Hz, 160 Hz, 1250 Hz and 8000 Hz, whereas the decrease maxima (lowest points T of the equalisation curve 10) are at 63 Hz, 400 Hz/500 Hz and 3150 Hz. There are therefore maxima at 25 Hz, 63 Hz, 160 Hz, 400 Hz, 1250 Hz, 3150 Hz and 8000 Hz. The amount of damping of these frequencies for a given loudness is: 7.5 dB, 5 dB, 5 dB, 4 dB, 3 dB, 2 dB and 1 dB.

FIGS. 1A and 1B show equalisation curves 10 which were produced with a commercially available equaliser. Music of different styles which was equalised with such an equalisation curve 10 was perceived as “most natural” in numerous hearing tests. It should be noted that a multiplication of the frequency of 25 Hz of the first extreme with the factor k=1.618² fairly precisely delivers the frequency of the second extreme: 25×1.618²=65.5 Hz. Equally, multiplication of the frequency of 63 Hz of the second extreme very precisely delivers the frequency of the third extreme: 63 Hz×1.618²=165 Hz etc.

It can be assumed that an equaliser which allows an even more accurate adjustment will result in the frequencies of the extremes of the equalisation curve 10 to be given precisely through multiplication with 1.1618 m² so that in an optimum equalisation curve 10 the empirically found law of the golden ratio is reflected.

It should be noted that the high points H and upwardly reflected low points T on the zero dB line lie on a straight line 14 (included in FIG. 1B for the sake of clarity). Additionally, the high points H (low points T) of adjacent amplitudes preferably lie by a maximum of 1.5 dB below (above) the value of the high point H (low point T), wherein “adjacent” relates to the neighbouring regulators of the aforementioned equaliser.

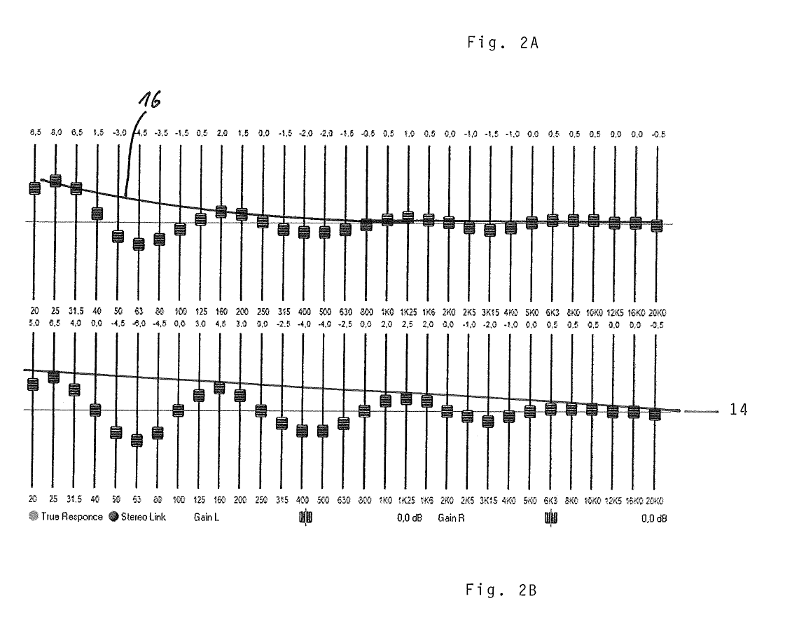

FIGS. 2A and 2B compare an equalisation curve 10 according to FIG. 1 (bottom) with an equalisation curve 10 according to a second form of embodiment (top).

As shown in FIG. 2A, in the second form of embodiment, using the same form of illustration (logarithmic entry of the frequencies), although the extremes lie at the same frequencies as in the first form of embodiment, they are not on a straight line. This means that the dB correction at the relevant frequencies is different. Correction by way of this equalisation curve 10 provides a further improvement in natural perception compared with a correction by way of the equalisation curve 10 according to the first form of embodiment.

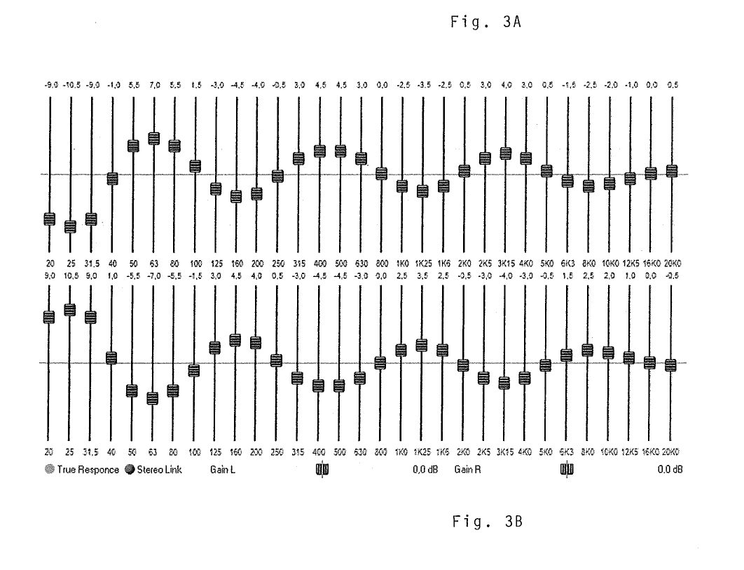

FIGS. 3A and 3B compare an equalisation curve 10 according to FIG. 1 (bottom) with a hearing sensitivity curve (top).

As stated above, both curves are a mirror reflection of each other, so that the “natural weaknesses” of human hearing are compensated.

1. An equaliser for the aurally compensated equalisation of a sound mix of sounds of different frequencies (f) according to an equalisation curve (P(f)) which shows a frequency-dependent changes in sound levels (P) of the sounds and at frequencies of f₍ₙ₎^{E}=kⁿ·f₀ has extremes (P(n)≡P(f(_{fn})) and at frequencies of f₍ₙ₎^{N}=k^{(n-1/2)}·f₀ zero points (N(n)≡N(f₍ₙ₎), with n ε N, f₀ as a frequency of a predetermined extreme (P(0)) and 1.5²≦k≦1.8².

2. The equaliser according to claim 1, characterised in that |P(n)|>|P(n+1)|∀n

3. The equaliser according to claim 2, characterised in that |P(n)|−|P(n+1)|=constant ∀n.

4. The equaliser according to claim 3, characterised in that |P(n)|−|P(n+1)|≦2 dB ∀n.

5. The equaliser according to claim 2, characterised in that |P(n)|−|P(n+1)|>|P(n+1)|−|P(n+2)|∀n.

6. The equaliser according to claim 1, characterised in that
$$\vert \frac{P ( n )}{P ( n + 1 )} \vert$$
becomes greater for a given value of n with increasing loudness of the sound mix.

7. The equaliser according to claim 1, characterised in that f₀=1.2 kHz.

8. The equaliser according to claim 1, characterised in that for each frequency interval f₍ₙ₎^{N}≦f≦f₍ₙ₊₁₎^{N} is either
$$\frac{{d}^{2}}{d {f}^{2}} P ( f ) < 0 or \frac{{d}^{2}}{d {f}^{2}} P ( f ) > 0.$$

9. The equaliser according to claim 1, characterised in that the frequency-dependent change in sound levels (P) is a frequency-dependent increase and/or decrease of the sound levels (P).

10. An audio system with an input, an output and a sound transducer connected to the output, characterised in that it comprises an equaliser according to claim 1 which in a reproduction chain of the audio system is arranged upstream of the sound transducer.

11. A method of aurally compensated equalisation of a sound mix of sounds of different frequencies (f), characterised in that the extent of equalisation is determined by an equalisation curve (P(f)) which shows a frequency-dependent change in sound levels (P) of the sounds and at frequencies of f₍ₙ₎^{E}=kⁿ·f₀ has extremes (P(n)≡P(f_{(fn)})and at frequencies of f₍ₙ₎^{N}=k^{(n-1/2)}·f₀ zero points (N(n)=N(f₍ₙ₎), with n ε N, f₀ as a frequency of a predetermined extreme (P(0)) and 1.5²≦k≦1.8².

12. The method according to claim 11, characterised in that the equalisation curve (P(f) has the shape of damped oscillation which attenuates with increasing frequency of the sound mix.

13. The method according to claim 12, characterised in that the ratio
$$\vert \frac{P ( n )}{P ( n + 1 )} \vert$$
becomes greater with increasing loudness of the sound mix.

14. The equaliser according to claim 2, characterised in that
$$\vert \frac{P ( n )}{P ( n + 1 )} \vert$$
becomes greater for a given value of n with increasing loudness of the sound mix.

15. The equaliser according to claim 2, characterised in that f₀=1.2 kHz.

16. The equaliser according to claim 2, characterised in that for each frequency interval f₍ₙ₎^{N}≦f≦f₍ₙ₊₁₎^{N} is either
$$\frac{{d}^{2}}{d {f}^{2}} P ( f ) < 0 or \frac{{d}^{2}}{d {f}^{2}} P ( f ) > 0.$$

17. The equaliser according to claim 2, characterised in that the frequencv-dependent change in sound levels (P) is a frequency-dependent increase and/or decrease of the sound levels (P).

18. The equaliser according to claim 3, characterised in that
$$\vert \frac{P ( n )}{P ( n + 1 )} \vert$$
becomes greater for a given value of n with increasing loudness of the sound mix.

19. The equaliser according to claim 3, characterised in that f₀=1.2 kHz.

20. The equaliser according to claim 3, characterised in that for each frequency interval f₍ₙ₎^{N}≦f≦f₍ₙ₊₁₎^{N} is either
$$\frac{{d}^{2}}{d {f}^{2}} P ( f ) < 0 or \frac{{d}^{2}}{d {f}^{2}} P ( f ) > 0.$$
